(19) United States
(12) Patent Application Publication
(10) Pub. No.: US 2026/0053053 A1
(43) Pub. Date: Feb. 19, 2026

(54) SEMICONDUCTOR PACKAGE AND METHOD OF MANUFACTURING THE SAME

(71) Applicant: Samsung Electronics Co., Ltd., Suwon-si (KR)

(72) Inventor: In Hee YOO, Suwon-si (KR)

(21) Appl. No.: 19/198,404

(22) Filed: May 5, 2025

(30) Foreign Application Priority Data
Aug. 16, 2024 (KR) 10-2024-0109896

(51) Int. Cl. H01L 23/31; H01L 23/00; H01L 23/34; H01L 23/498; H01L 25/07

(52) U.S. Cl. CPC H01L 23/3135; H01L 23/34; H01L 23/562; H01L 24/48; H01L 23/498; H01L 25/074; H01L 2224/48227; H01L 2225/0651; H01L 2225/06562; H01L 2225/06589

(57) ABSTRACT

A semiconductor package comprises a package substrate, a first semiconductor chip comprising a semiconductor substrate, a wiring structure on the semiconductor substrate, a connection pad at an uppermost part of the wiring structure, and a protective layer on a side surface of the connection pad, a crack reduction layer on the connection pad and the protective layer and a mold layer on the crack reduction layer, wherein a coefficient of thermal expansion of the crack reduction layer is lower than a coefficient of thermal expansion of the semiconductor substrate.

### CROSS-REFERENCE TO RELATED APPLICATION

This application claims priority from Korean Patent Application No. 10-2024-0109896, filed on Aug. 16, 2024, in the Korean Intellectual Property Office, and all the benefits accruing therefrom under 35 U.S. C. 119, the contents of which in its entirety are herein incorporated by reference.

### BACKGROUND

### 1. Field

The present disclosure relates to a semiconductor package and a method of manufacturing the same.

### 2. Description of the Related Art

A semiconductor package is an implementation of integrated circuit (IC) chips in a form suitable for use in an electronic product. Typically, a semiconductor package is fabricated by mounting semiconductor chips on a printed circuit board (PCB) and electrically connecting them using bonding wires or bumps. With the development of the electronics industry, various studies are being conducted to improve the reliability of semiconductor packages.

Additionally, as the storage capacity of semiconductor chips increases, there is a growing demand for a semiconductor packages containing these semiconductor chips to become thinner and lighter.

### SUMMARY

Aspects of the present disclosure may provide a semiconductor package with improved reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor package comprising a package substrate, a first semiconductor chip comprising a semiconductor substrate, a wiring structure on the semiconductor substrate, a connection pad at an uppermost part of the wiring structure, and a protective layer on a side surface of the connection pad, a crack reduction layer on the connection pad and the protective layer, and a mold layer on the crack reduction layer, wherein a coefficient of thermal expansion of the crack reduction layer is lower than a coefficient of thermal expansion of the semiconductor substrate.

According to the aforementioned and some embodiments of the present disclosure, a semiconductor package comprises a package substrate comprising a first electrode pad, a first semiconductor chip comprising a semiconductor substrate, a wiring structure on a first surface of the semiconductor substrate, a plurality of connection pads on the wiring structure, and a protective layer on a side surface of the connection pads, a crack reduction layer on a second surface of the semiconductor substrate, a mold layer on the crack reduction layer, a connection member electrically connecting the connection pads and the first electrode pad and an underfill covering the connection member, wherein a coefficient of thermal expansion of the crack reduction layer is lower than a coefficient of thermal expansion of the semiconductor substrate.

According to the aforementioned and some embodiments of the present disclosure, a semiconductor package comprises a package substrate, a first semiconductor chip comprising a semiconductor substrate, a wiring structure on the semiconductor substrate, a connection pad at an uppermost part of the wiring structure, and a protective layer on a side surface of the connection pad, a crack reduction layer on the first semiconductor chip and on the connection pad and the protective layer, and a mold layer on the crack reduction layer, wherein a coefficient of thermal expansion of the crack reduction layer is lower than a coefficient of thermal expansion of the semiconductor substrate, the first semiconductor chip directly contacts the crack reduction layer, and a distance between an upper surface of the mold layer and the upper surface of the crack reduction layer is larger than a thickness of the crack reduction layer.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a top view illustrating a semiconductor package according to some embodiments of the present disclosure.

FIGS. 2 and 3 are cross-sectional views taken along line I-I′ of FIG. 1.

FIGS. 4 through 9 are cross-sectional views illustrating a method of manufacturing a semiconductor package according to some embodiments of the present disclosure.

FIG. 10 is a cross-sectional view illustrating the effects of the semiconductor package according to some embodiments of the present disclosure.

FIGS. 11 through 13 are cross-sectional views illustrating semiconductor packages according to some embodiments of the present disclosure.

FIG. 14 is a top view illustrating a semiconductor package according to some embodiments of the present disclosure.

FIG. 15 is a cross-sectional views taken along line II-II′ of FIG. 14.

FIGS. 16 to 20 is a section illustration of a method for the preparation of a semiconductor package of FIG. 15.

FIG. 21 is a cross-sectional views taken along line II-II′ of FIG. 14.

FIGS. 22 to 26 are a section illustration of a method for the preparation of a semiconductor package of FIG. 21.

FIG. 27 is a cross-sectional views taken along line II-II′ of FIG. 14.

### DETAILED DESCRIPTION

Embodiments of the present disclosure will hereinafter be described in detail with reference to the accompanying drawings. The same reference numerals are used for the same components in the drawings, and redundant explanations thereof will be omitted.

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, description of some conventional elements or parts are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Likewise, when components are “immediately” adjacent to one another, no intervening components may be present. Further, in the specification, the word “on” or “above” may include on or below the object portion, and does not necessarily mean positioned on the upper side of the object portion based on a gravitational direction.

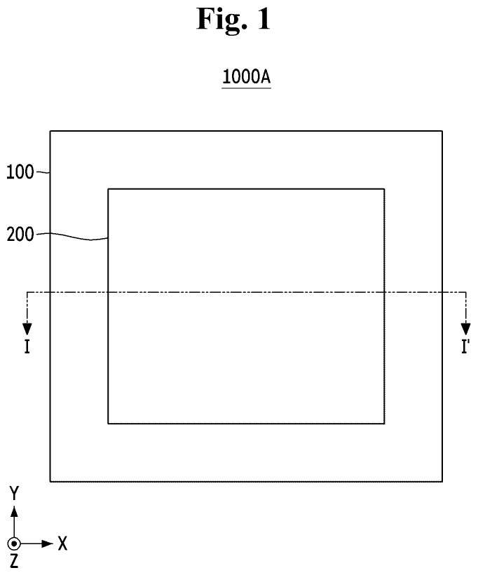

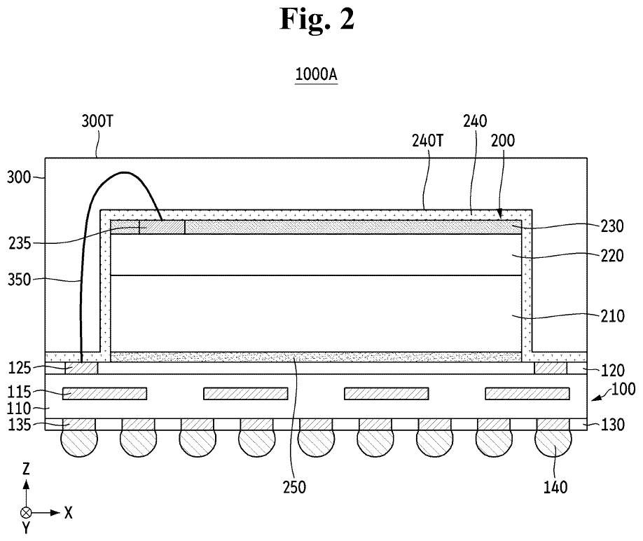

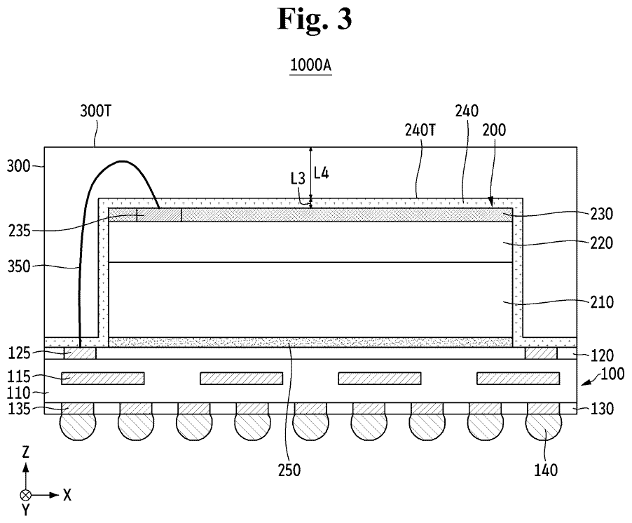

The terms “first,” “second,” etc., may be used herein merely to distinguish one component, layer, direction, etc. from another. In addition, unless explicitly described to the contrary, the word “comprise” and variations such as “comprises” or “comprising” will be understood to imply the inclusion of stated elements but not the exclusion of any other elements. The term “and/or” includes any and all combinations of one or more of the associated listed items. The term “connected” may be used herein to refer to a physical and/or electrical connection. FIG. 1 is a top view illustrating a semiconductor package according to some embodiments of the present disclosure. FIGS. 2 and 3 are cross-sectional views taken along line I-I′ of FIG. 1.

Referring to FIGS. 1 and 2, a semiconductor package 1000A according to some embodiments of the present disclosure may include a semiconductor chip 200, a package substrate 100, and a mold layer 300.

The package substrate 100 may be a substrate for a semiconductor package that includes a printed circuit board (PCB), a ceramic substrate, a glass substrate, or a tape wiring substrate.

The semiconductor chip 200 may be on one surface (i.e., the upper surface) of the package substrate 100. The semiconductor chip 200 may be fixed onto the package substrate 100 by an adhesive layer 250. The adhesive layer 250 may be, for example, a die adhesive film (DAF), but the present disclosure is not limited thereto.

The package substrate 100 may include a plurality of external connection terminals 140 on the other surface (i.e., the lower surface) of the package substrate 100. The external connection terminals 140 may be formed of a conductive material and may be in the shape of balls or pins.

The package substrate 100 may include an active layer 110. The active layer 110 may include an internal wiring structure 115. The internal wiring structure 115 may be arranged in a plurality of layers. For example, the internal wiring structure 115 may be arranged in a single layer, but the present disclosure is not limited thereto. Alternatively, the internal wiring structure 115 may be arranged in two or three layers.

Additionally, the package substrate 100 may include a first protective layer 120 on one surface and a second protective layer 130 on the other surface. First electrode pads 125 are on one surface of the package substrate 100 and are exposed without being covered by the first protective layer 120. The exposed first electrode pads 125 may be electrically connected to connection pads 235 of the semiconductor chip 200 through wires 350. Second electrode pads 135 are on the other surface of the package substrate 100 and are exposed without being covered by the second protective layer 130. The exposed second electrode pads 135 are directly connected to the external connection terminals 140.

The semiconductor chip 200 may include a semiconductor substrate 210, a wiring structure 220, a protective layer 230, and a crack reduction layer 240. The crack reduction layer 240 may be configured to reduce or prevent cracks.

The semiconductor substrate 210 may include, for example, a semiconductor element such as silicon (Si) or germanium (Ge), or a compound semiconductor such as silicon carbide (SiC), gallium arsenide (GaAs), indium arsenide (InAs), or indium phosphide (InP).

The wiring structure 220 may be on the upper surface of the semiconductor substrate 210. The wiring structure 220 may include various types of active elements and/or passive elements. For example, the wiring structure 220 may include a field-effect transistor (FET) such as a planar FET or a fin FET (FinFET), a memory element such as a flash memory, a dynamic random-access memory (DRAM), a static random-access memory (SRAM), an electrically erasable programmable read-only memory (EEPROM), a phase-change random-access memory (PRAM), a magnetoresistive random-access memory (MRAM), a ferroelectric random-access memory (FeRAM), a resistive random-access memory (RRAM), a logic element such as an AND, OR, or NOT element, a system large-scale integration (LSI), a complementary metal-oxide semiconductor (CMOS) imaging sensor (CIS), a micro-electromechanical system (MEMS), and other various active and/or passive elements.

The connection pads 235 may be on the upper surface of the wiring structure 220. The protective layer 230 may be around the connection pads 235.

The connection pads 235 may be electrically connected to the first electrode pads 125 of the package substrate 100 through the wires 350.

The protective layer 230 may be on the upper surface of the wiring structure 220. The protective layer 230 may include an element with a higher coefficient of thermal expansion than the semiconductor substrate 210 and the crack reduction layer 240. The protective layer 230 may be formed of a photosensitive material such as a photosensitive polyimide (PSPI). For example, the coefficient of thermal expansion of the protective layer 230 may be approximately 20 ppm/° C. to 60 ppm/° C.

The crack reduction layer 240 may be on the upper surfaces and side surfaces of the package substrate 100, the protective layer 230, and the connection pads 235.

In some embodiments, the crack reduction layer 240 may be deposited as a thin film through chemical vapor deposition (CVD). For example, the crack reduction layer 240 may be formed by thermal CVD, low-pressure CVD (LPCVD), or plasma-enhanced CVD (PECVD).

In some embodiments, the crack reduction layer 240 may be formed after electrically connecting the package substrate 100 and the semiconductor chip 200 via the wires 350. As a result, the crack reduction layer 240 may be on or entirely cover the semiconductor chip 200 and the package substrate 100, which may increase the effect of the present disclosure in offsetting tensile stress with compressive stress. The specific effects of the present disclosure will be described later.

Additionally, the crack reduction layer 240 may be on or cover ends of the wires 350 that contact the connection pads 235, the first electrode pads 125, and other ends of the wires 350 that contact the first electrode pads 125. Consequently, wire sweep may be reduced or prevented. In other words, the performance and reliability of the semiconductor package 1000A can be improved. The crack reduction layer 240 may include an insulating material and an element with a lower coefficient of thermal expansion than the semiconductor substrate 210. For example, the semiconductor substrate 210 may include an element such as Si, and the crack reduction layer 240 may include an element such as silicon dioxide (SiO₂). For example, the coefficient of thermal expansion of the semiconductor substrate 210 may be approximately 2.6 ppm/° C., and the coefficient of thermal expansion of the crack reduction layer 240 may be approximately 0.5 ppm/° C.

The mold layer 300 may be on or encapsulate the side surfaces and upper surfaces of the package substrate 100 and the crack reduction layer 240. The mold layer 300 may include, for example, an epoxy mold compound (EMC), but the present disclosure is not limited thereto.

Referring to FIG. 3, in some embodiments of the present disclosure, the thickness of the crack reduction layer 240 included in the semiconductor package 1000A may be smaller than the thickness of the mold layer 300 measured from the upper surface of the crack reduction layer 240.

For example, the thickness of the crack reduction layer 240 measured from the upper surface of the protective layer 230 may be L3, and the thickness of the mold layer 300 measured from the upper surface 240T of the crack reduction layer 240 may be L4. Here, L3 may be smaller than L4.

By securing a sufficient mold gap or distance (i.e., L4 in FIG. 3), cracks can be reduced or prevented from occurring at the uppermost part of the semiconductor chip 200 during an indentation hardness test.

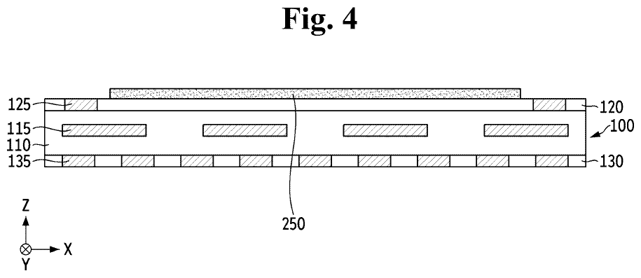

FIGS. 4 through 9 are cross-sectional views illustrating a method of manufacturing a semiconductor package according to some embodiments of the present disclosure.

Referring to FIG. 4, an adhesive layer 250 may be on a package substrate 100. The adhesive layer 250 may be, for example, a DAF, but the present disclosure is not limited thereto.

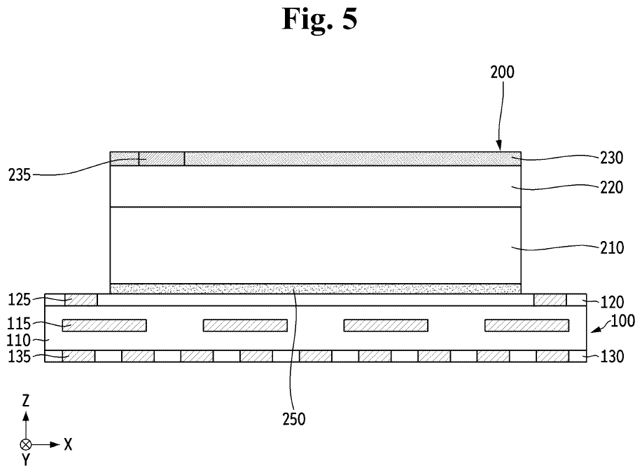

Referring to FIG. 5, a semiconductor chip 200 may be on one surface (i.e., the upper surface) of the package substrate 100. The semiconductor chip 200 may be fixed onto the package substrate 100 by the adhesive layer 250.

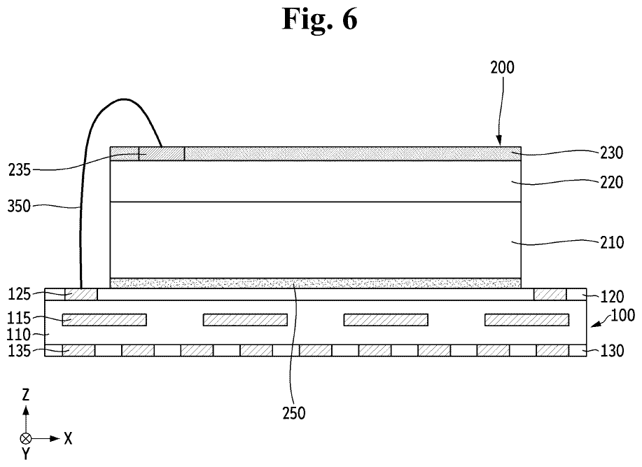

Referring to FIG. 6, first electrode pads 125 of the package substrate 100 may be electrically connected to connection pads 235 of the semiconductor chip 200 through wires 350.

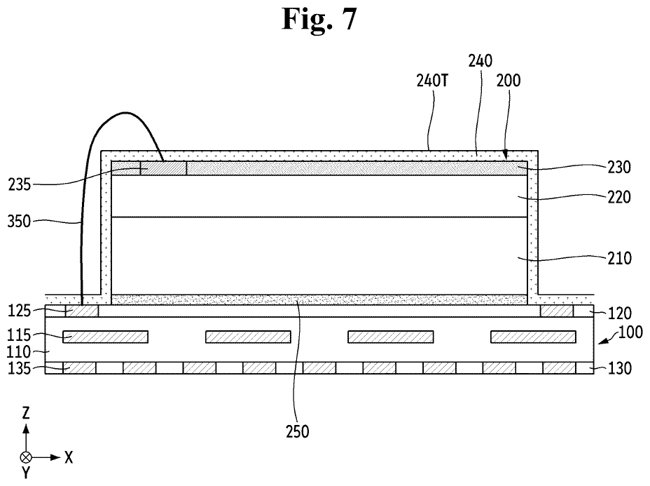

Referring to FIG. 7, a crack reduction layer 240 may be formed on the package substrate 100 and the semiconductor chip 200. In some embodiments, the crack reduction layer 240 may be deposited as a thin film through CVD. For example, the crack reduction layer 240 may be formed by thermal CVD, LPCVD, or PECVD.

As the crack reduction layer 240 is formed after electrically connecting the package substrate 100 and the semiconductor chip 200 via the wires 350, the crack reduction layer 240 can entirely cover the semiconductor chip 200 and the package substrate 100. As a result, the effect of the present disclosure in offsetting tensile stress with compressive stress can be increased or maximized. The specific effects of the present disclosure will be described later.

Additionally, as the crack reduction layer 240 is formed after electrically connecting the package substrate 100 and the semiconductor chip 200 via the wires 350, the crack reduction layer 240 can cover ends of the wires 350 that contact the connection pads 235, the first electrode pads 125, and other ends of the wires 350 that contact the first electrode pads 125. Consequently, wire sweep can be reduced or prevented. In other words, the performance and reliability of a semiconductor package 1000A can be improved.

The crack reduction layer 240 may include an insulating material and an element with a lower coefficient of thermal expansion than the semiconductor substrate 210. For example, the semiconductor substrate 210 may include an element such as Si, and the crack reduction layer 240 may include a compound such as SiO₂. For example, the coefficient of thermal expansion of the semiconductor substrate 210 may be approximately 2.6 ppm/° C., and the coefficient of thermal expansion of the crack reduction layer 240 may be approximately 0.5 ppm/° C.

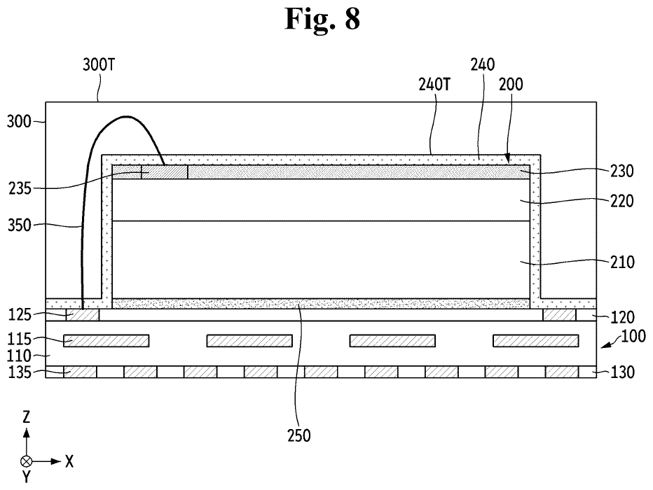

Referring to FIG. 8, a mold layer 300 that is on or encapsulates the side surfaces and upper surfaces of the package substrate 100 and the crack reduction layer 240 may be formed. The mold layer 300 may include, for example, an EMC, but the present disclosure is not limited thereto.

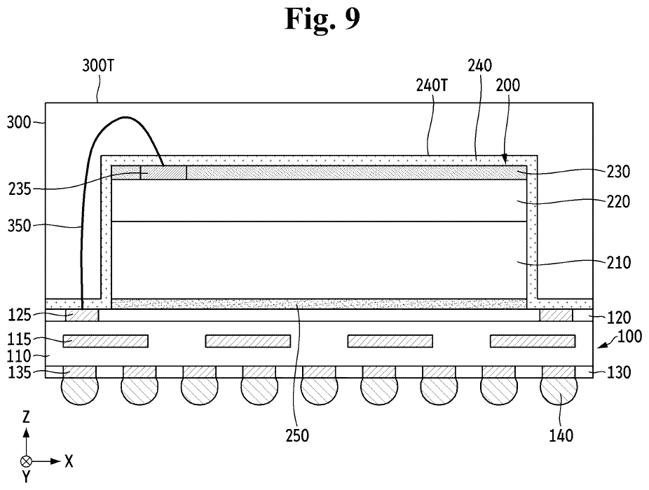

Referring to FIG. 9, a plurality of external connection terminals 140 may be attached to the second electrode pads 135 of the package substrate 100. The external connection terminals 140 may connect the semiconductor package 1000A to the outside.

In some embodiments, the external connection terminals 140 may be formed of a conductive material and may be in the shape of balls or pins. The external connection terminals 140 may be formed of, for example, copper (Cu), aluminum (Al), silver (Ag), tin (Sn), gold (Au), or solder, but the present disclosure is not limited thereto.

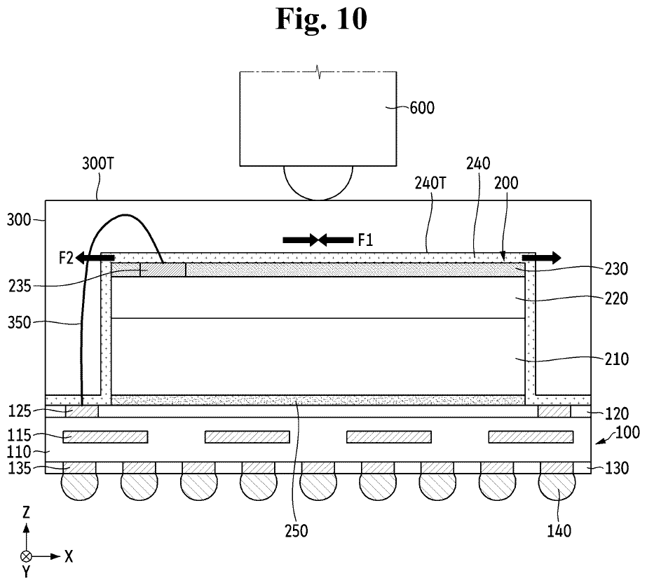

FIG. 10 is a cross-sectional view illustrating the effects of the semiconductor package according to some embodiments of the present disclosure.

Referring to FIG. 10, an indentation hardness test may be performed on the completed semiconductor package 1000A using an indenter 600.

In some embodiments, compressive stress F1 may be applied to the semiconductor substrate 210 by the indenter 600. The compressive stress F1 may be applied in a first direction (i.e., a direction toward the center of the semiconductor substrate 210).

In some embodiments, the crack reduction layer 240 may include an element with a lower coefficient of thermal expansion than the semiconductor substrate 210. The semiconductor substrate 210 may include an element such as Si, and the crack reduction layer 240 may include a compound such as SiO₂. For example, the coefficient of thermal expansion of the semiconductor substrate 210 may be approximately 2.6 ppm/° C., and the coefficient of thermal expansion of the crack reduction layer 240 may be approximately 0.5 ppm/° C.

In some embodiments, after melting an EMC at a high temperature of, for example, approximately 175° C. and then cooling it to room temperature, the semiconductor substrate 210 and the crack reduction layer 240 may contract to different extents due to the difference in their coefficients of thermal expansion. For example, the coefficient of thermal expansion of the semiconductor substrate 210 may be a1, and the coefficient of thermal expansion of the crack reduction layer 240 may be a2. Here, a1 may be greater than a2.

As the temperature changes from high to low (e.g., to room temperature), the amount of contraction of the semiconductor substrate 210, which has the thermal expansion coefficient a1, may be greater than that of the crack reduction layer 240, which has the thermal expansion coefficient a2. In other words, the crack reduction layer 240 may apply tensile stress F2 to the semiconductor substrate 210. The tensile stress F2 may be applied in a second direction (i.e., a direction away from the center of the semiconductor substrate 210) that is opposite to the first direction.

Through this, the tensile stress F2 can offset the compressive stress F1 applied to the semiconductor substrate 210 by the indenter 600. As a result, the fracture load of the semiconductor package 1000A can be increased, the thickness of the semiconductor chip 200 can be increased or maximized, the reliability of the semiconductor package 1000A can be improved, and crack formation may be reduced or prevented.

Additionally, the crack reduction layer 240 can cover the ends of the wires 350 that contact the connection pads 235, the first electrode pads 125, and the ends of the wires 350 that contact the first electrode pads 125. Consequently, wire sweep can be reduced or prevented. In other words, the performance and reliability of the semiconductor package 1000A can be improved.

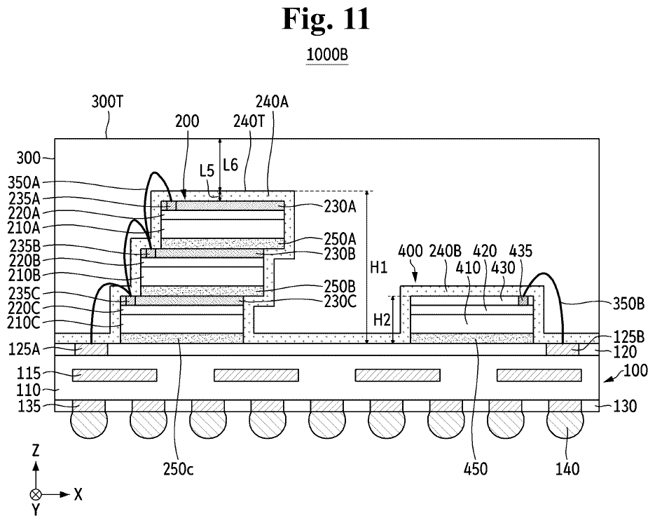

FIGS. 11 through 13 are cross-sectional views illustrating semiconductor packages according to some embodiments of the present disclosure.

Referring to FIG. 11, a semiconductor package 1000B according to some embodiments of the present disclosure may include a first semiconductor chip 200, a second semiconductor chip 400, and a mold layer 300 on a package substrate 100.

The package substrate 100 may be a substrate for a semiconductor package, including a PCB, a ceramic substrate, a glass substrate, or a tape wiring substrate.

The first and second semiconductor chips 200 and 400 may be on one surface (i.e., the upper surface) of the package substrate 100 and may be spaced apart from each other. The first and second semiconductor chips 200 and 400 may be fixed onto the package substrate 100 by an adhesive layer 250. The adhesive layer 250 may be, for example, a DAF, but the present disclosure is not limited thereto.

The package substrate 100 may include a plurality of external connection terminals 140 on the other surface (i.e., the lower surface). The external connection terminals 140 may be formed of a conductive material and may be in the shape of balls or pins.

The package substrate 100 may include an active layer 110. The active layer 110 may include an internal wiring structure 115. Additionally, the package substrate 100 may include a first protective layer 120 on one surface and a second protective layer 130 on the other surface. First electrode pads (125A and 125B) are on one surface of the package substrate 100 and are exposed without being covered by the first protective layer 120. Exposed first sub-electrode pads 125A may be electrically connected to first sub-connection pads 235A, second sub-connection pads 235B, and third sub-connection pads 235C of the first semiconductor chip 200 through first sub-wires 350A. Exposed second sub-electrode pads 125B may be electrically connected to fourth sub-connection pads 435 of the second semiconductor chip 400 through second sub-wires 350B. Second electrode pads 135 are on the other surface of the package substrate 100 and are exposed without being covered by the second protective layer 130. The exposed second electrode pads 135 are directly connected to the external connection terminals 140.

A plurality of first, second, and third sub-semiconductor chips of the first semiconductor chip 200 and the second semiconductor chip 400 may include semiconductor substrates 210A, 210B, 210C, and 410, respectively, wiring structures 220A, 220B, 220C, and 420, respectively, protective layer 230A, 230B, 230C, and 430, respectively, and a crack reduction layer (240A and 240B). The first, second, and third sub-semiconductor chips of the first semiconductor chip 200 and the second semiconductor chip 400 may be the same as or similar to the semiconductor chip 200 of any one of FIGS. 1 through 10, and thus, detailed descriptions thereof will be omitted.

The crack reduction layer (240A and 240B) may be along the upper surfaces and side surfaces of the package substrate 100, the first semiconductor chip 200, and the second semiconductor chip 400.

In some embodiments, the crack reduction layer (240A and 240B) may be formed after electrically connecting the package substrate 100, the first semiconductor chip 200, and the second semiconductor chip 400 via the first sub-wires 350A and the second sub-wires 350B. Consequently, the crack reduction layer (240A and 240B) can entirely cover the first semiconductor chip 200, the second semiconductor chip 400, and the package substrate 100, thereby increasing the effect of offsetting compressive stress with tensile stress.

Additionally, the crack reduction layer (240A and 240B) can cover ends of the first sub-wires 350A that contact the first sub-connection pads 235A, the second sub-connection pads 235B, and the third sub-connection pads 235C, the first electrode pads 125A, and other ends of the first sub-wires 350A that contact the first electrode pads 125A. The crack reduction layer (240A and 240B) can also cover ends of the second sub-wires 350B that contact the fourth sub-connection pads 435 and the first electrode pads 125B and other ends of the second sub-wires 350B that contact the first electrode pads 125B. Wire sweep can be reduced or prevented. That is, the performance and reliability of the semiconductor package 1000B can be improved. The crack reduction layer (240A and 240B) may include an insulating material and an element with a lower coefficient of thermal expansion than the semiconductor substrates 210A, 210B, 210C, and 410. For example, the semiconductor substrates 210A, 210B, 210C, and 410 may include an element such as Si, and the crack reduction layer (240A and 240B) may include a compound such as SiO₂. For example, the coefficient of thermal expansion of the semiconductor substrates 210A, 210B, 210C, and 410 may be approximately 2.6 ppm/° C., and the coefficient of thermal expansion of the crack reduction layer (240A and 240B) may be approximately 0.5 ppm/° C.

The mold layer 300 may be on or encapsulate the side surfaces and upper surfaces of the package substrate 100 and the crack reduction layer (240A and 240B). The mold layer 300 may include, for example, an EMC, but the present disclosure is not limited thereto.

In some embodiments, the height of the first semiconductor chip 200 may be greater than the height of the second semiconductor chip 400. For example, the height of the first semiconductor chip 200 measured from the upper surface of the package substrate 100 may be H1, and the height of the second semiconductor chip 400 measured from the upper surface of the package substrate 100 may be H2. Here, H1 may be greater than H2.

In some embodiments, the thickness of the crack reduction layer (240A and 240B) included in the semiconductor package 1000B may be smaller than the thickness of the mold layer 300 measured from the upper surface of the crack reduction layer (240A and 240B). In this case, the upper surface of the crack reduction layer (240A and 240B) refers to the uppermost surface from the package substrate 100. For example, since the height of the first semiconductor chip 200 is greater than the height of the second semiconductor chip 400, the upper surface of the crack reduction layer (240A and 240B) may be located on the upper surface of the sub-protective layer 230A at the uppermost part of the first semiconductor chip 200. The thickness of the crack reduction layer (240A and 240B) measured from the upper surface of the sub-protective layer 230A of the first sub-semiconductor chip may be L5, and the thickness of the mold layer 300 measured from an upper surface 240T of the crack reduction layer (240A and 240B) may be L6. Here, L5 may be smaller than L6.

By securing a sufficient mold gap or distance (L6 in FIG. 11), cracks can be reduced or prevented from occurring at the uppermost part of the first semiconductor chip 200 during an indentation hardness test.

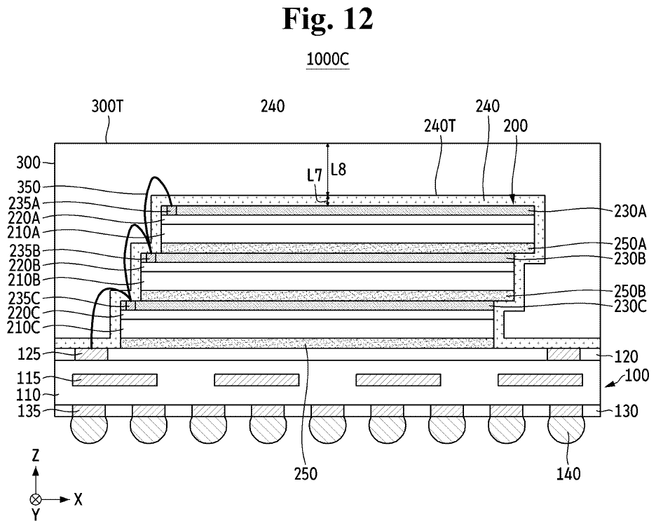

Referring to FIG. 12, a semiconductor package 1000C according to some embodiments of the present disclosure may include a semiconductor chip 200 and a mold layer 300 on a package substrate 100.

The package substrate 100 may be a substrate for a semiconductor package, including a PCB, a ceramic substrate, a glass substrate, or a tape wiring substrate.

The semiconductor chip 200 may be on one surface (i.e., the upper surface) of the package substrate 100. The semiconductor chip 200 may be fixed onto the package substrate 100 by an adhesive layer 250. The adhesive layer 250 may be, for example, a DAF, but the present disclosure is not limited thereto.

The package substrate 100 may include a plurality of external connection terminals 140 on the other surface (i.e., the lower surface). The external connection terminals 140 may be formed of a conductive material and may be in the shape of balls or pins.

The package substrate 100 may include an active layer 110. The active layer 110 may include an internal wiring structure 115. Additionally, the package substrate 100 may include a first protective layer 120 on one surface and a second protective layer 130 on the other surface. First electrode pads 125 are on one surface of the package substrate 100 and are exposed without being covered by the first protective layer 120. The exposed first electrode pads 125 may be electrically connected to first sub-connection pads 235A, second sub-connection pads 235B, and third sub-connection pads 235C of the semiconductor chip 200 through wires 350. Second electrode pads 135 are on the other surface of the package substrate 100 and are exposed without being covered by the second protective layer 130. The exposed second electrode pads 135 are directly connected to the external connection terminals 140.

A plurality of first, second, and third sub-semiconductor chips of the semiconductor chip 200 may include semiconductor substrate 210A, 210B, and 210C, respectively, wiring structures 220A, 220B, and 220C, respectively, protective layers 230A, 230B, and 230C, respectively, and a crack reduction layer 240. The first, second, and third sub-semiconductor chips of the semiconductor chip 200 may be the same as or similar to the semiconductor chip 200 of any one of FIGS. 1 through 10, and thus, detailed descriptions thereof will be omitted.

The crack reduction layer 240 may be along the upper surfaces and side surfaces of the package substrate 100 and the semiconductor chip 200.

In some embodiments, the crack reduction layer 240 may be formed after electrically connecting the package substrate 100 and the semiconductor chip 200 via the wires 350. Consequently, the crack reduction layer 240 can entirely cover the semiconductor chip 200 and the package substrate 100, thereby increasing or maximizing the effect of the present disclosure in offsetting compressive stress with tensile stress.

Additionally, the crack reduction layer 240 can cover ends of the wires 350 that contact the first sub-connection pads 235A, the second sub-connection pads 235B, and the third sub-connection pads 235C, the first electrode pads 125, and other ends of the wires 350 that contact the first electrode pads 125. Consequently, wire sweep can be reduced or prevented. In other words, the performance and reliability of the semiconductor package 1000C can be improved.

The crack reduction layer 240 may include an insulating material and an element with a lower coefficient of thermal expansion than the semiconductor substrates 210A, 210B, and 210C. For example, the semiconductor substrates 210A, 210B, and 210C may include an element such as Si, and the crack reduction layer 240 may include a compound such as SiO₂. For example, the coefficient of thermal expansion of the semiconductor substrates 210A, 210B, and 210C may be approximately 2.6 ppm/° C., and the coefficient of thermal expansion of the crack reduction layer 240 may be approximately 0.5 ppm/° C.

The mold layer 300 may be on or encapsulate the side surfaces and upper surfaces of the package substrate 100 and the crack reduction layer 240. The mold layer 300 may include, for example, an EMC, but the present disclosure is not limited thereto.

In some embodiments, the thickness of the crack reduction layer 240 included in the semiconductor package 1000C may be smaller than the thickness of the mold layer 300 measured from the upper surface of the crack reduction layer 240. The thickness of the crack reduction layer 240 measured from the upper surface of the sub-protective layer 230A of the first sub-semiconductor chip may be L7, and the thickness of the mold layer 300 measured from an upper surface 240T of the crack reduction layer 240 may be L8. Here, L7 may be smaller than L8.

By securing a sufficient mold gap or distance (L8 in FIG. 11), cracks can be reduced or prevented from occurring at the uppermost part of the semiconductor chip 200 during an indentation hardness test.

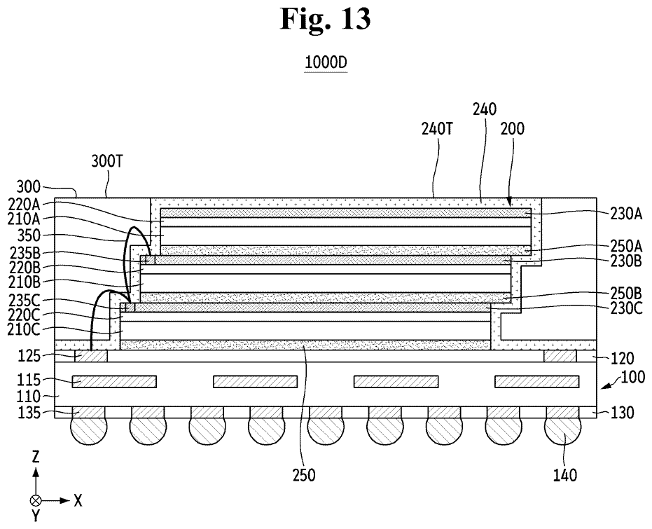

Referring to FIG. 13, a semiconductor package 1000D according to some embodiments of the present disclosure may include a semiconductor chip 200 and a mold layer 300 on a package substrate 100.

The package substrate 100 may be a substrate for a semiconductor package, including a PCB, a ceramic substrate, a glass substrate, or a tape wiring substrate.

The semiconductor chip 200 may be on one surface (i.e., the upper surface) of the package substrate 100. The semiconductor chip 200 may be fixed onto the package substrate 100 by an adhesive layer 250. The adhesive layer 250 may be, for example, a DAF, but the present disclosure is not limited thereto.

The package substrate 100 may include a plurality of external connection terminals 140 on the other surface (i.e., the lower surface). The external connection terminals 140 may be formed of a conductive material and may be in the shape of balls or pins.

The package substrate 100 may include an active layer 110. The active layer 110 may include an internal wiring structure 115. Additionally, the package substrate 100 may include a first protective layer 120 on one surface and a second protective layer 130 on the other surface. First electrode pads 125 are on one surface of the package substrate 100 and are exposed without being covered by the first protective layer 120. The exposed first electrode pads 125 may be electrically connected to first sub-connection pads 235A, second sub-connection pads 235B, and third sub-connection pads 235C of the semiconductor chip 200 through wires 350. Second electrode pads 135 are on the other surface of the package substrate 100 and are exposed without being covered by the second protective layer 130. The exposed second electrode pads 135 are directly connected to the external connection terminals 140.

A plurality of first, second, and third sub-semiconductor chips of the semiconductor chip 200 may include semiconductor substrates 210A, 210B, and 210C, respectively, wiring structures 220A, 220B, and 220C, respectively, protective layers 230A, 230B, and 230C, respectively, and a crack reduction layer 240. The first, second, and third sub-semiconductor chips of the semiconductor chip 200 may be the same as or similar to the semiconductor chip 200 of any one of FIGS. 1 through 10, and thus, detailed descriptions thereof will be omitted.

The crack reduction layer 240 may be along the upper surfaces and side surfaces of the package substrate 100 and the semiconductor chip 200.

In some embodiments, the crack reduction layer 240 may be formed after electrically connecting the package substrate 100 and the semiconductor chip 200 via the wires 350. Consequently, the crack reduction layer 240 can entirely cover the semiconductor chip 200 and the package substrate 100, thereby increasing or maximizing the effect of the present disclosure in offsetting compressive stress with tensile stress.

Additionally, the crack reduction layer 240 can cover ends of the wires 350 that contact the second sub-connection pads 235B and 235C, the first electrode pads 125, and other ends of the wires 350 that contact the first electrode pads 125. Consequently, wire sweep can be reduced or prevented. In other words, the performance and reliability of the semiconductor package 1000D can be improved.

The crack reduction layer 240 may include an insulating material and an element with a lower coefficient of thermal expansion than the semiconductor substrates 210A, 210B, and 210C. For example, the semiconductor substrates 210A, 210B, and 210C may include an element such as Si, and the crack reduction layer 240 may include a compound such as SiO₂. For example, the coefficient of thermal expansion of the semiconductor substrates 210A, 210B, and 210C may be approximately 2.6 ppm/° C., and the coefficient of thermal expansion of the crack reduction layer 240 may be approximately 0.5 ppm/° C.

The mold layer 300 may be on or encapsulate the side surfaces and upper surfaces of the package substrate 100 and the crack reduction layer 240. The mold layer 300 may include, for example, an EMC, but the present disclosure is not limited thereto.

In some embodiments, an upper surface 240T of the crack reduction layer 240 and an upper surface 300T of the mold layer 300 may be positioned parallel to one another. This secures the fracture load by the crack reduction layer 240 while ensuring sufficient chip thickness. In other words, a semiconductor package 1000D with improved reliability can be provided.

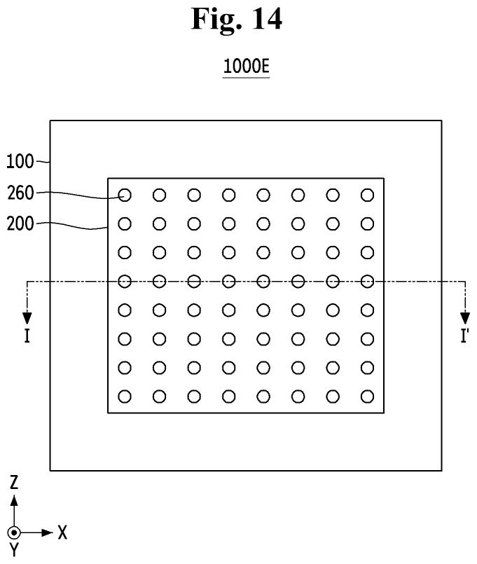

FIG. 14 is a top view illustrating a semiconductor package according to some embodiments of the present disclosure.

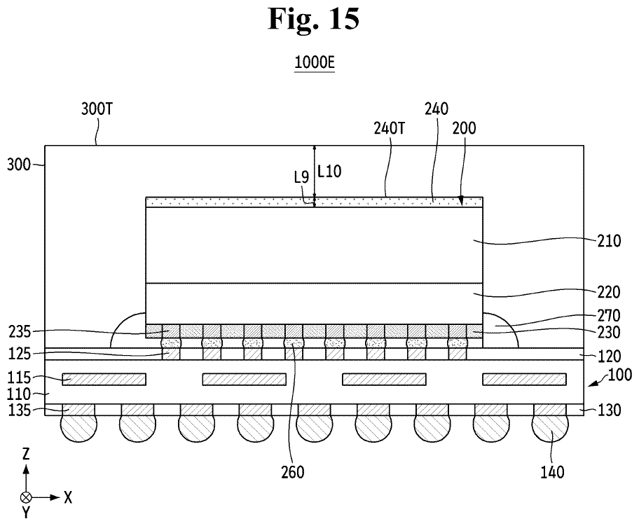

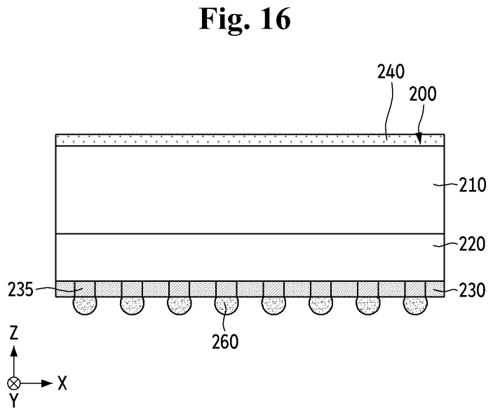

FIGS. 15 and 16 are cross-sectional views taken along line II-II′ of FIG. 14.

Referring to FIGS. 14 and 15, a semiconductor package 1000E according to some embodiments of the present disclosure may include a semiconductor chip 200, a package substrate 100, and a mold layer 300.

The package substrate 100 may be a substrate for a semiconductor package, including a PCB, a ceramic substrate, a glass substrate, or a tape wiring substrate.

The semiconductor chip 200 may be on one surface (i.e., the upper surface) of the package substrate 100. The semiconductor chip 200 may be mounted on the package substrate 100 by a flip chip bonding method using a plurality of microbumps 260. An underfill 270 may be interposed between the semiconductor chip 200 and the upper surface of the package substrate 100. The underfill 270 may surround the microbumps 260.

The package substrate 100 may include a plurality of external connection terminals 140 on the other surface (i.e., the lower surface). The external connection terminals 140 may be formed of a conductive material and may be in the shape of balls or pins.

The package substrate 100 may include an active layer 110. The active layer 110 may include an internal wiring structure 115. The internal wiring structure 115 may be arranged in a plurality of layers. For example, the internal wiring structure 115 may be arranged in a single layer, but the present disclosure is not limited thereto. Alternatively, the internal wiring structure 115 may be arranged in two or three layers.

Additionally, the package substrate 100 may include a first protective layer 120 on one surface and a second protective layer 130 on the other surface. First electrode pads 125 are on one surface of the package substrate 100 and are exposed without being covered by the first protective layer 120. The exposed first electrode pads 125 may be electrically connected to connection pads 235 of the semiconductor chip 200 through the microbumps 260. Second electrode pads 135 are on the other surface of the package substrate 100 and are exposed without being covered by the second protective layer 130. The exposed second electrode pads 135 are directly connected to the external connection terminals 140.

The semiconductor chip 200 may include a semiconductor substrate 210, a wiring structure 220, a protective layer 230, and a crack reduction layer 240.

The semiconductor substrate 210 may include, for example, a semiconductor element such as Si or Ge, or a compound semiconductor such as SiC, GaAs, InAs, or InP.

The wiring structure 220 may be on the lower surface of the semiconductor substrate 210. The wiring structure 220 may include various types of active elements and/or passive elements. For example, the wiring structure 220 may include a planar FET or a FinFET, a memory element such as a flash memory, a DRAM, an SRAM, an EEPROM, a PRAM, an MRAM, a FeRAM, an RRAM, a logic element such as an AND, OR, or NOT gate, a system LSI, a CIS, an MEMS, and other various active and/or passive elements.

The connection pads 235 may be on the lower surface of the wiring structure 220. The protective layer 230 may be around the connection pads 235.

The connection pads 235 may be electrically connected to the first electrode pads 125 of the package substrate 100 through the microbumps 260.

The protective layer 230 may be on the lower surface of the wiring structure 220. The protective layer 230 may include an element with a higher coefficient of thermal expansion than the semiconductor substrate 210 and the crack reduction layer 240. The protective layer 230 may be formed of a photosensitive material such as a PSPI. For example, the coefficient of thermal expansion of the protective layer 230 may be approximately 20 ppm/° C. to 60 ppm/° C.

The crack reduction layer 240 may be on the upper surface of the semiconductor chip 200.

In some embodiments, the crack reduction layer 240 may be deposited as a thin film through CVD. For example, the crack reduction layer 240 may be formed by thermal CVD, LPCVD, or PECVD.

In some embodiments, the crack reduction layer 240 may be formed before mounting the semiconductor chip 200 on the package substrate 100. Compressive stress can be offset by the tensile stress of the crack reduction layer 240, thereby increasing the fracture load of the semiconductor package 1000E. The specific effects of the present disclosure will be described later.

The crack reduction layer 240 may include an insulating material and an element with a lower coefficient of thermal expansion than the semiconductor substrate 210. For example, the semiconductor substrate 210 may include an element such as Si, and the crack reduction layer 240 may include a compound such as SiO₂. For example, the coefficient of thermal expansion of the semiconductor substrate 210 may be approximately 2.6 ppm/° C., and the coefficient of thermal expansion of the crack reduction layer 240 may be approximately 0.5 ppm/° C.

The mold layer 300 may be on or encapsulate the side surfaces and upper surfaces of the package substrate 100, the crack reduction layer 240, and the semiconductor chip 200. The mold layer 300 may include, for example, an EMC, but the present disclosure is not limited thereto.

In some embodiments, the thickness of the crack reduction layer 240 included in the semiconductor package 1000E may be smaller than the thickness of the mold layer 300 measured from the upper surface of the crack reduction layer 240.

For example, the thickness of the crack reduction layer 240 measured from the upper surface of the semiconductor chip 200 may be L9, and the thickness of the mold layer 300 measured from an upper surface 240T of the crack reduction layer 240 may be L10. Here, L9 may be smaller than L10.

By securing a sufficient mold gap or distance (L10 in FIG. 16), cracks can be reduced or prevented from occurring at the uppermost part of the semiconductor chip 200 during an indentation hardness test.

FIGS. 16 to 20 is a section illustration of a method for the preparation of a semiconductor package of FIG. 15.

Referring to FIG. 16, the crack reduction layer 240 may be formed on the semiconductor substrate 210 of the semiconductor chip 200. In some embodiments, the crack reduction layer 240 may be deposited as a thin film through CVD. For example, the crack reduction layer 240 may be formed by thermal CVD, LPCVD, or PECVD.

The crack reduction layer 240 may include an insulating material and an element with a lower coefficient of thermal expansion than the semiconductor substrate 210. For example, the semiconductor substrate 210 may include an element such as Si, and the crack reduction layer 240 may include a compound such as SiO₂. For example, the coefficient of thermal expansion of the semiconductor substrate 210 may be approximately 2.6 ppm/° C., and the coefficient of thermal expansion of the crack reduction layer 240 may be approximately 0.5 ppm/° C.

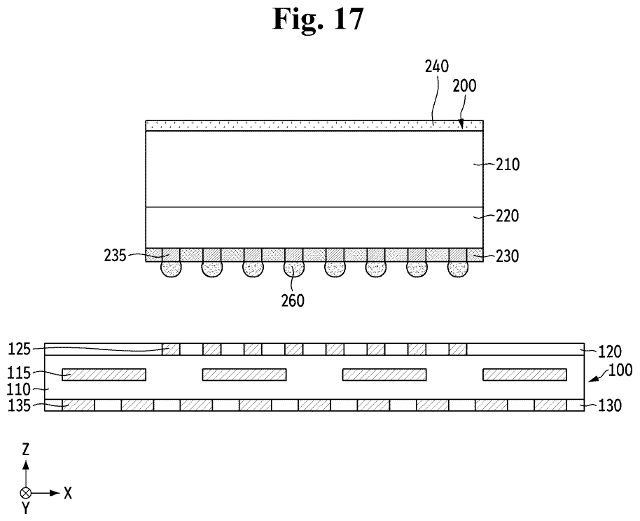

Referring to FIG. 17, the semiconductor chip 200 with the crack reduction layer 240 may be mounted on the package substrate 100 by a flip chip bonding method using a plurality of microbumps 260.

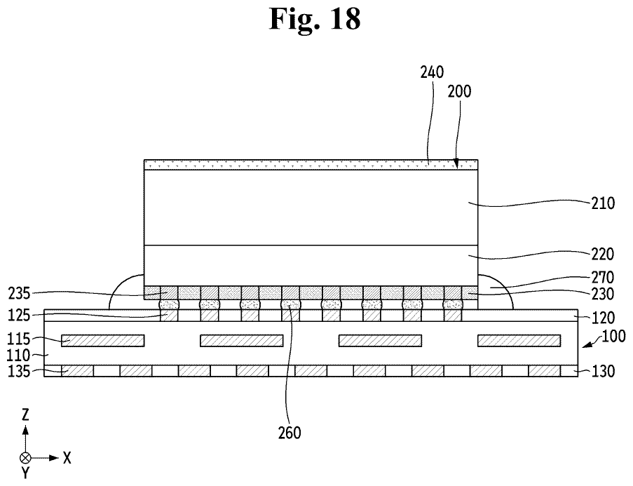

Referring to FIG. 18, an underfill 270 may be interposed between the semiconductor chip 200 and the upper surface of the package substrate 100. The underfill 270 may surround the microbumps 260.

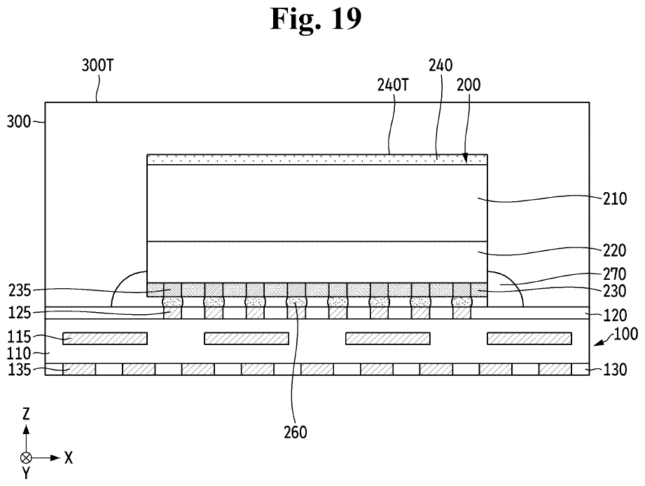

Referring to FIG. 19, a mold layer 300 that is on or encapsulates the side surfaces and upper surfaces of the package substrate 100, the crack reduction layer 240, and the semiconductor chip 200 may be formed. The mold layer 300 may include, for example, an EMC, but the present disclosure is not limited thereto.

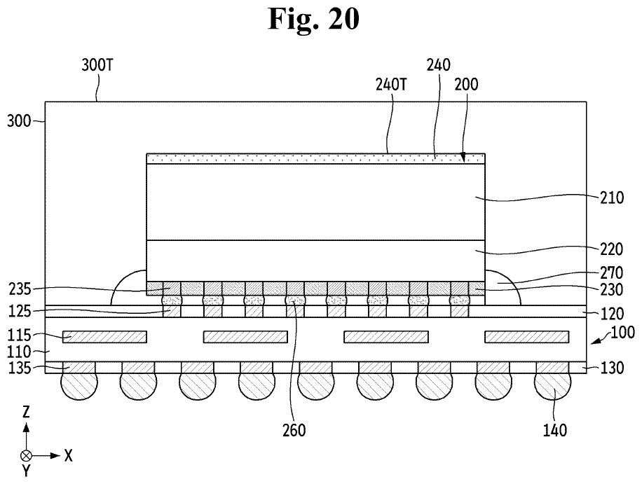

Referring to FIG. 20, a plurality of external connection terminals 140 may be attached to the second electrode pads 135 of the package substrate 100. The external connection terminals 140 may connect the semiconductor package 1000E to the outside.

In some embodiments, the external connection terminals 140 may be formed of a conductive material and may be in the shape of balls or pins. The plurality of external connection terminals 140 may be formed of, for example, Cu, Al, Ag, Sn, Au, or solder, but the present disclosure is not limited thereto.

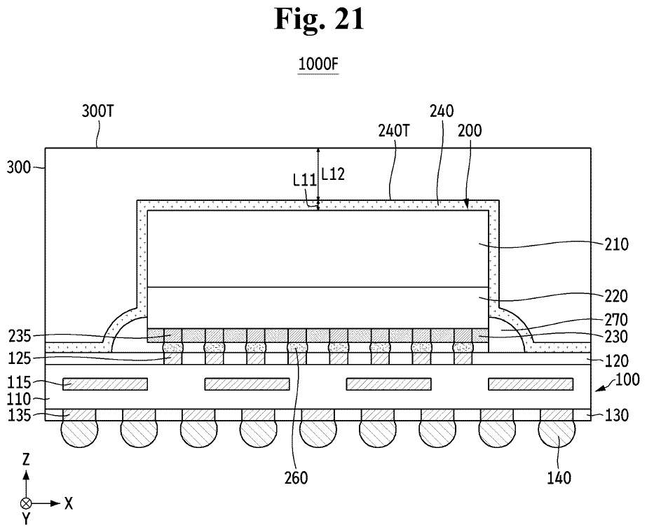

FIG. 21 is a cross-sectional views taken along line II-II′ of FIG. 14.

Referring to FIG. 21, a semiconductor package 1000F according to some embodiments of the present disclosure may include a semiconductor chip 200, a package substrate 100, and a mold layer 300.

The package substrate 100 may be a substrate for a semiconductor package, including a PCB, a ceramic substrate, a glass substrate, or a tape wiring substrate.

The semiconductor chip 200 may be on one surface (i.e., the upper surface) of the package substrate 100. The semiconductor chip 200 may be mounted on the package substrate 100 by a flip chip bonding method using a plurality of microbumps 260. An underfill 270 may be interposed between the semiconductor chip 200 and the upper surface of the package substrate 100. The underfill 270 may surround the microbumps 260.

The package substrate 100 may include a plurality of external connection terminals 140 on the other surface (i.e., the lower surface). The external connection terminals 140 may be formed of a conductive material and may be in the shape of balls or pins.

The package substrate 100 may include an active layer 110. The active layer 110 may include an internal wiring structure 115. The internal wiring structure 115 may be arranged in a plurality of layers. For example, the internal wiring structure 115 may be arranged in a single layer, but the present disclosure is not limited thereto. Alternatively, the internal wiring structure 115 may be arranged in two or three layers.

Additionally, the package substrate 100 may include a first protective layer 120 on one surface and a second protective layer 130 on the other surface. First electrode pads 125 are on one surface of the package substrate 100 and are exposed without being covered by the first protective layer 120. The exposed first electrode pads 125 may be electrically connected to the connection pads 235 of the semiconductor chip 200 through the microbumps 260. Second electrode pads 135 are on the other surface of the package substrate 100 and are exposed without being covered by the second protective layer 130. The exposed second electrode pads 135 are directly connected to the external connection terminals 140.

The semiconductor chip 200 may include a semiconductor substrate 210, a wiring structure 220, a protective layer 230, and a crack reduction layer 240.

The semiconductor substrate 210 may include, for example, a semiconductor element such as Si or Ge, or a compound semiconductor such as SiC, GaAs, InAs, or InP.

The wiring structure 220 may be on the upper surface of the semiconductor substrate 210. The wiring structure 220 may include various types of active elements and/or passive elements. For example, the wiring structure 220 may include a planar FET or a FinFET, a memory element such as a flash memory, a DRAM, an SRAM, an EEPROM, a PRAM, an MRAM, a FeRAM, an RRAM, a logic element such as an AND, OR, or NOT gate, a system LSI, a CIS, an MEMS, and other various active and/or passive elements.

The connection pads 235 may be on the upper surface of the wiring structure 220. The protective layer 230 may be around the connection pads 235.

The connection pads 235 may be electrically connected to the first electrode pads 125 of the package substrate 100 through the microbumps 260.

The protective layer 230 may be on the upper surface of the wiring structure 220. The protective layer 230 may include an element with a higher coefficient of thermal expansion than the semiconductor substrate 210 and the crack reduction layer 240. The protective layer 230 may be formed of a photosensitive material such as a PSPI. For example, the coefficient of thermal expansion of the protective layer 230 may be approximately 20 ppm/° C. to 60 ppm/° C.

The crack reduction layer 240 may be along the upper surfaces and side surfaces of the package substrate 100, the underfill 270, and the semiconductor chip 200.

In some embodiments, the crack reduction layer 240 may be deposited as a thin film through CVD. For example, the crack reduction layer 240 may be formed by thermal CVD, LPCVD, or PECVD.

In some embodiments, the crack reduction layer 240 may be formed after the package substrate 100 and the semiconductor chip 200 are electrically connected via the microbumps 260. Consequently, the crack reduction layer 240 can entirely cover the semiconductor chip 200 and the package substrate 100, thereby increasing or maximizing the effect of the present disclosure in offsetting compressive stress with tensile stress. The specific effects of the present disclosure will be described later.

The crack reduction layer 240 may include an insulating material and an element with a lower coefficient of thermal expansion than the semiconductor substrate 210. For example, the semiconductor substrate 210 may include an element such as Si, and the crack reduction layer 240 may include a compound such as SiO₂. For example, the coefficient of thermal expansion of the semiconductor substrate 210 may be approximately 2.6 ppm/° C., and the coefficient of thermal expansion of the crack reduction layer 240 may be approximately 0.5 ppm/° C.

The mold layer 300 may be on or encapsulate the side surfaces and upper surfaces of the package substrate 100 and the crack reduction layer 240. The mold layer 300 may include, for example, an EMC, but the present disclosure is not limited thereto.

In some embodiments, the thickness of the crack reduction layer 240 included in the semiconductor package 1000F may be smaller than the thickness of the mold layer 300 measured from the upper surface of the crack reduction layer 240.

For example, the thickness of the crack reduction layer 240 measured from the upper surface of the semiconductor chip 200 may be L11, and the thickness of the mold layer 300 measured from an upper surface 240T of the crack reduction layer 240 may be L12. Here, L11 may be smaller than L12.

By securing a sufficient mold gap or distance (L12 in FIG. 16), cracks can be reduced or prevented from occurring at the uppermost part of the semiconductor chip 200 during an indentation hardness test.

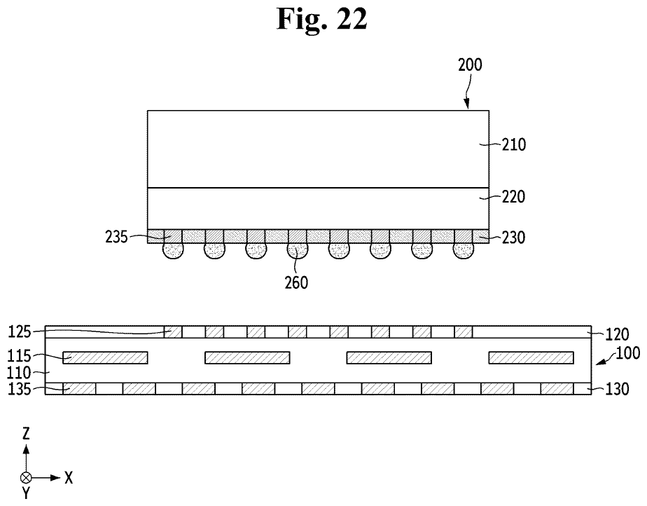

FIGS. 22 to 26 are a section illustration of a method for the preparation of a semiconductor package of FIG. 21.

Referring to FIG. 22, the semiconductor chip 200 may be mounted on the package substrate 100 by a flip chip bonding method using a plurality of microbumps 260.

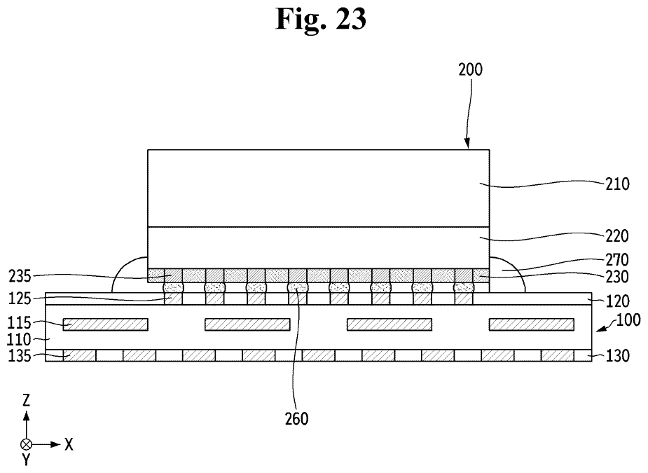

Referring to FIG. 23, an underfill 270 may be interposed between the semiconductor chip 200 and the upper surface of the package substrate 100. The underfill 270 may surround the microbumps 260.

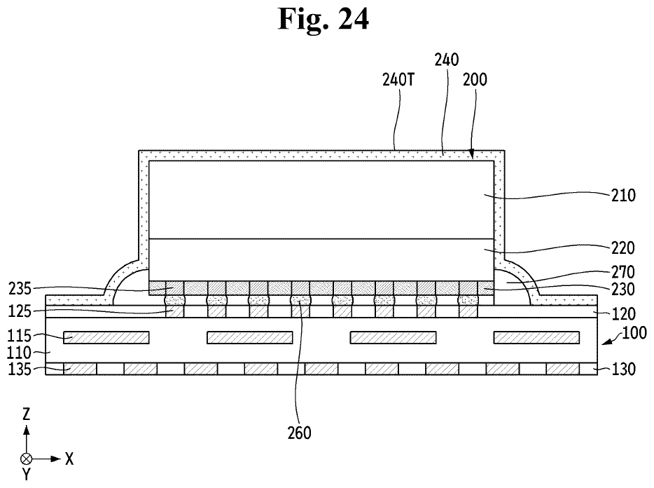

Referring to FIG. 24, the crack reduction layer 240 may be formed on the package substrate 100 and the semiconductor chip 200. In some embodiments, the crack reduction layer 240 may be deposited as a thin film through CVD. For example, the crack reduction layer 240 may be formed by thermal CVD, LPCVD, or PECVD.

The crack reduction layer 240 may include an insulating material and an element with a lower coefficient of thermal expansion than the semiconductor substrate 210. For example, the semiconductor substrate 210 may include an element such as Si, and the crack reduction layer 240 may include a compound such as SiO₂. For example, the coefficient of thermal expansion of the semiconductor substrate 210 may be approximately 2.6 ppm/° C., and the coefficient of thermal expansion of the crack reduction layer 240 may be approximately 0.5 ppm/° C.

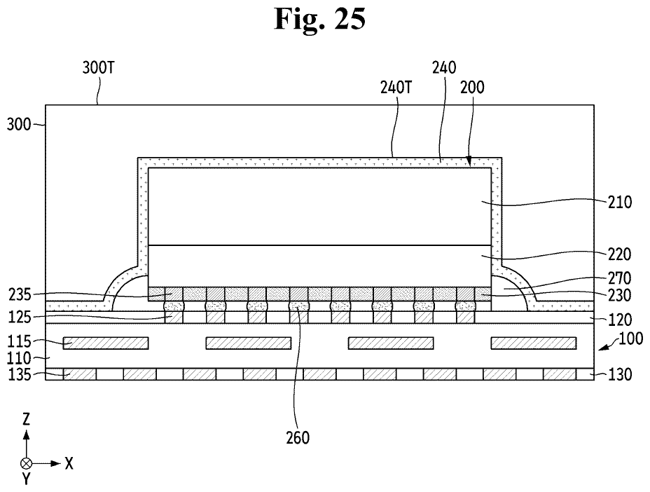

Referring to FIG. 25, a mold layer 300 that be on or encapsulates the side surfaces and upper surfaces of the package substrate 100 and the crack reduction layer 240 may be formed. The mold layer 300 may include, for example, an EMC, but the present disclosure is not limited thereto.

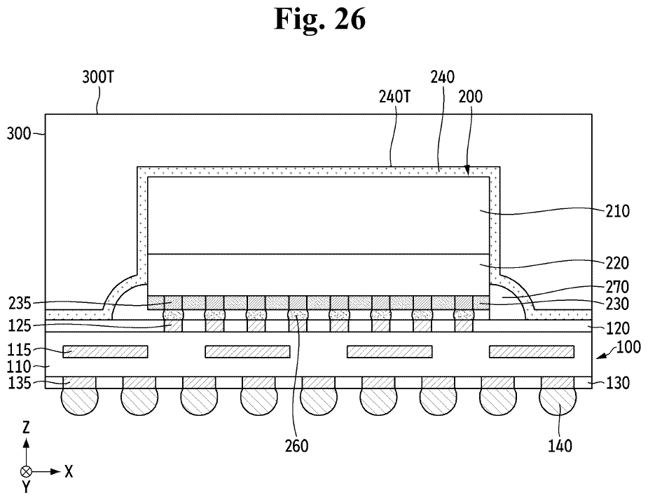

Referring to FIG. 26, a plurality of external connection terminals 140 may be attached to the second electrode pads 135 of the package substrate 100. The external connection terminals 140 may connect the semiconductor package 1000F to the outside.

In some embodiments, the external connection terminals 140 may be formed of a conductive material and may be in the shape of balls or pins. The external connection terminals 140 may be formed of, for example, Cu, Al, Ag, Sn, Au, or solder, but the present disclosure is not limited thereto.

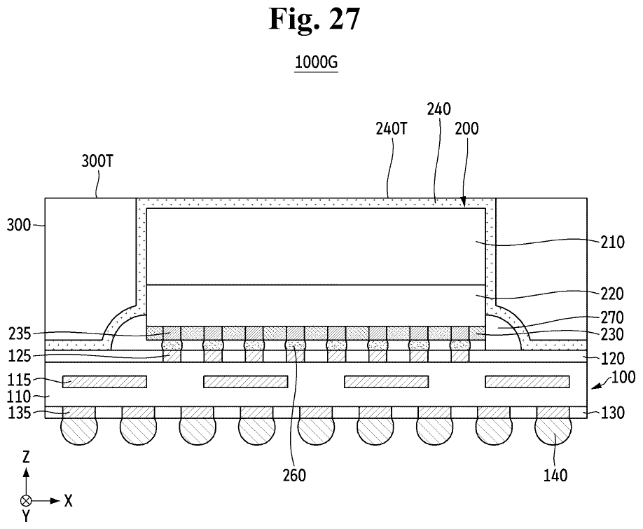

FIG. 27 is a cross-sectional views taken along line II-II′ of FIG. 14.

Referring to FIG. 27, a semiconductor package 1000G according to some embodiments of the present disclosure may include a semiconductor chip 200, a package substrate 100, and a mold layer 300.

The package substrate 100 may be a substrate for a semiconductor package, including a PCB, a ceramic substrate, a glass substrate, or a tape wiring substrate.

The semiconductor chip 200 may be on one surface (i.e., the upper surface) of the package substrate 100. The semiconductor chip 200 may be mounted on the package substrate 100 by a flip chip bonding method using a plurality of microbumps 260. An underfill 270 may be interposed between the semiconductor chip 200 and the upper surface of the package substrate 100. The underfill 270 may surround the microbumps 260.

The package substrate 100 may include a plurality of external connection terminals 140 on the other surface (i.e., the lower surface). The external connection terminals 140 may be formed of a conductive material and may be in the shape of balls or pins.

The package substrate 100 may include an active layer 110. The active layer 110 may include an internal wiring structure 115. The internal wiring structure 115 may be arranged in a plurality of layers. For example, the internal wiring structure 115 may be arranged in a single layer, but the present disclosure is not limited thereto. Alternatively, the internal wiring structure 115 may be arranged in two or three layers.

Additionally, the package substrate 100 may include a first protective layer 120 on one surface and a second protective layer 130 on the other surface. First electrode pads 125 are on one surface of the package substrate 100 and are exposed without being covered by the first protective layer 120. The exposed first electrode pads 125 may be electrically connected to the connection pads 235 of the semiconductor chip 200 through the microbumps 260. Second electrode pads 135 are on the other surface of the package substrate 100 and are exposed without being covered by the second protective layer 130. The exposed second electrode pads 135 are directly connected to the external connection terminals 140.

The semiconductor chip 200 may include a semiconductor substrate 210, a wiring structure 220, a protective layer 230, and a crack reduction layer 240.

The semiconductor substrate 210 may include, for example, a semiconductor element such as Si or Ge, or a compound semiconductor such as SiC, GaAs, InAs, or InP.

The wiring structure 220 may be on the upper surface of the semiconductor substrate 210. The wiring structure 220 may include various types of active elements and/or passive elements. For example, the wiring structure 220 may include a planar FET, a FinFET, a memory element such as a flash memory, a DRAM, an SRAM, an EEPROM, a PRAM, an MRAM, a FeRAM, an RRAM, a logic element such as an AND, OR, or NOT gate, a system LSI, a CIS, an MEMS, and other various active and/or passive elements.

The connection pads 235 may be on the upper surface of the wiring structure 220. The protective layer 230 may be around the connection pads 235.

The connection pads 235 may be electrically connected to the first electrode pads 125 of the package substrate 100 through the microbumps 260.

The protective layer 230 may be on the upper surface of the wiring structure 220. The protective layer 230 may include an element with a higher coefficient of thermal expansion than the semiconductor substrate 210 and the crack reduction layer 240. The protective layer 230 may be formed of a photosensitive material such as a PSPI. For example, the coefficient of thermal expansion of the protective layer 230 may be approximately 20 ppm/° C. to 60 ppm/° C.

The crack reduction layer 240 may be along the upper surfaces and side surfaces of the package substrate 100, the underfill 270, and the semiconductor chip 200.

In some embodiments, the crack reduction layer 240 may be deposited as a thin film through CVD. For example, the crack reduction layer 240 may be formed by thermal CVD, LPCVD, or PECVD.

In some embodiments, the crack reduction layer 240 may be formed after electrically connecting the package substrate 100 and the semiconductor chip 200 via the microbumps 260. Consequently, the crack reduction layer 240 can entirely cover the semiconductor chip 200 and the package substrate 100, thereby increasing or maximizing the effect of the present disclosure in offsetting compressive stress with tensile stress. The specific effects of the present disclosure will be described later.

The crack reduction layer 240 may include an insulating material and an element with a lower coefficient of thermal expansion than the semiconductor substrate 210. For example, the semiconductor substrate 210 may include an element such as Si, and the crack reduction layer 240 may include a compound such as SiO₂. For example, the coefficient of thermal expansion of the semiconductor substrate 210 may be approximately 2.6 ppm/° C., and the coefficient of thermal expansion of the crack reduction layer 240 may be approximately 0.5 ppm/° C.

The mold layer 300 may be on or encapsulate the side surfaces and upper surfaces of the package substrate 100 and the crack reduction layer 240. The mold layer 300 may include, for example, an EMC, but the present disclosure is not limited thereto.

In some embodiments, an upper surface 240T of the crack reduction layer 240 and an upper surface 300T of the mold layer 300 may be positioned parallel to one another. This secures the fracture load by the crack reduction layer 240 while ensuring sufficient chip thickness. In other words, a semiconductor package 1000G with improved reliability can be provided.

While the embodiments of the present disclosure have been described with reference to the accompanying drawings, the present disclosure is not limited to the embodiments described above and may be embodied in various forms. Those skilled in the art will appreciate that other specific forms may be implemented without changing the technical spirit or essential features of the present disclosure. Therefore, the embodiments described above are illustrative in all aspects and should not be understood as limiting.

What is claimed is:

1. A semiconductor package comprising:
a package substrate;
a first semiconductor chip comprising a semiconductor substrate, a wiring structure on the semiconductor substrate, a connection pad at an uppermost part of the wiring structure, and a protective layer on a side surface of the connection pad;
a crack reduction layer on the connection pad and the protective layer; and
a mold layer on the crack reduction layer,
wherein a coefficient of thermal expansion of the crack reduction layer is lower than a coefficient of thermal expansion of the semiconductor substrate.

2. The semiconductor package of claim 1, wherein the crack reduction layer directly contacts the connection pad and the protective layer.

3. The semiconductor package of claim 1, further comprising:
a first electrode pad on the package substrate,
wherein the first electrode pad and the connection pad are electrically connected through a wire, and
the crack reduction layer is on the first electrode pad.

4. The semiconductor package of claim 1, wherein a coefficient of thermal expansion of the protective layer is higher than coefficients of thermal expansion of the semiconductor substrate and the crack reduction layer.

5. The semiconductor package of claim 1, wherein
the semiconductor substrate includes silicon (Si), and
the crack reduction layer includes silicon dioxide (SiO₂).

6. The semiconductor package of claim 1, wherein the mold layer is on an upper surface of the crack reduction layer.

7. The semiconductor package of claim 6, wherein a distance between an upper surface of the mold layer and the upper surface of the crack reduction layer is larger than a thickness of the crack reduction layer.

8. The semiconductor package of claim 1, wherein an upper surface of the mold layer and an upper surface of the crack reduction layer are positioned parallel to one another.

9. The semiconductor package of claim 1, wherein
the first semiconductor chip includes a plurality of sub-semiconductor chips stacked on the package substrate,
the plurality of sub-semiconductor chips include a first sub-semiconductor chip at the uppermost part of the first semiconductor chip, and a second sub-semiconductor chip between the first sub-semiconductor chip and the package substrate,
the first sub-semiconductor chip includes a first sub-semiconductor substrate, a first sub-wiring structure on the first sub-semiconductor substrate, a first sub-connection pad at an uppermost part of the first sub-wiring structure, and a first sub-protective layer on a side surface of the first sub-connection pad,
the second sub-semiconductor chip includes a second sub-semiconductor substrate, a second sub-wiring structure on the second sub-semiconductor substrate, a second sub-connection pad at an uppermost part of the second sub-wiring structure, and a second sub-protective layer on a side surface of the second sub-connection pad, and
the crack reduction layer is on the first sub-connection pad, the second sub-connection pad, and the first sub-protective layer.

10. The semiconductor package of claim 1, further comprising:
a second semiconductor chip mounted on the package substrate,
wherein
an upper surface of the first semiconductor chip is higher than an upper surface of the second semiconductor chip,
a second crack reduction layer is on the second semiconductor chip, and
a distance between an upper surface of the mold layer and an upper surface of the crack reduction layer is larger than a thickness of the crack reduction layer.

11. The semiconductor package of claim 10, wherein the crack reduction layer extends along edges of the first semiconductor chip and the upper surface of the package substrate to contact the second crack reduction layer.

12. A semiconductor package comprising:
a package substrate including a first electrode pad;
a first semiconductor chip including a semiconductor substrate, a wiring structure on a first surface of the semiconductor substrate, a plurality of connection pads on the wiring structure, and a protective layer on a side surface of the connection pads;
a crack reduction layer on a second surface of the semiconductor substrate;
a mold layer on the crack reduction layer;
a connection member electrically connecting the connection pads and the first electrode pad; and
an underfill on the connection member,
wherein a coefficient of thermal expansion of the crack reduction layer is lower than a coefficient of thermal expansion of the semiconductor substrate.

13. The semiconductor package of claim 12, wherein the crack reduction layer directly contacts the semiconductor substrate.

14. The semiconductor package of claim 12, wherein the crack reduction layer is on the underfill, an upper surface of the package substrate, and both side surfaces of the first semiconductor chip.

15. The semiconductor package of claim 12, wherein both side surfaces of the first semiconductor chip directly contact the mold layer.

16. The semiconductor package of claim 12, wherein the mold layer is on an upper surface of the crack reduction layer.

17. The semiconductor package of claim 16, wherein a distance between an upper surface of the mold layer and the upper surface of the crack reduction layer is larger than a thickness of the crack reduction layer.

18. The semiconductor package of claim 12, wherein an upper surface of the mold layer and an upper surface of the crack reduction layer are positioned parallel to one another.

19. The semiconductor package of claim 12, wherein
the semiconductor substrate includes silicon (Si), and
the crack reduction layer includes silicon dioxide (SiO₂).

20. A semiconductor package comprising:
a package substrate;
a first semiconductor chip including a semiconductor substrate, a wiring structure on the semiconductor substrate, a connection pad at an uppermost part of the wiring structure, and a protective layer on a side surface of the connection pad;
a crack reduction layer on the first semiconductor chip and on the connection pad and the protective layer; and
a mold layer on the crack reduction layer,
wherein
a coefficient of thermal expansion of the crack reduction layer is lower than a coefficient of thermal expansion of the semiconductor substrate,
the first semiconductor chip directly contacts the crack reduction layer, and
a distance between an upper surface of the mold layer and the upper surface of the crack reduction layer is larger than a thickness of the crack reduction layer.
